(19) United States
(12) Patent Application Publication
(10) Pub. No.: US 2025/0120323 A1
(43) Pub. Date: Apr. 10, 2025

(54) SEMICONDUCTOR DEVICE AND MANUFACTURING METHOD THEREOF

(71) Applicant: TAIWAN SEMICONDUCTOR MANUFACTURING COMPANY, LTD., Hsinchu (TW)

(72) Inventors: Nien-Yu Tai, Hsinchu (TW); Kuo-Feng Huang, Hsinchu (TW); Yi-Jen HUANG, Hsinchu (TW); Yu-Jen WANG, Hsinchu (TW); HARRY-HAKLAY CHUANG, Hsinchu (TW)

(73) Assignee: TAIWAN SEMICONDUCTOR MANUFACTURING COMPANY, LTD., Hsinchu (TW)

(21) Appl. No.: 18/377,190

(22) Filed: Oct. 5, 2023

(51) Int. Cl. H10N 50/80; G11C 11/16; H10B 61/00; H10N 50/01; H10N 50/10

(52) U.S. Cl. CPC H10N 50/80; G11C 11/161; H10B 61/00; H10N 50/01; H10N 50/10

(57) ABSTRACT

A semiconductor device includes a plurality of interlayer dielectric layers, a memory cell, and a first capping layer. The memory cell is embedded in the interlayer dielectric layers, the first capping layer covers the memory cell and surrounds the sidewalls of the memory cell, the first capping layer includes a hydrogen absorbing material, and the hydrogen absorbing material prevents hydrogen gas from entering the memory cell.

### BACKGROUND

Many modern electronic devices contain electronic memories, such as a hard disk drive or random access memory (RAM). Electronic memory can be either volatile or non-volatile. Non-volatile memory retains its stored data in the absence of power, while volatile memory loses its data memory contents when power is lost. Magnetic tunnel junctions (MTJs) can be used in hard disk drives or random access memory, so they are a very promising solution for next-generation memory.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a magnetic tunnel junction memory cell.

FIG. 2 is a schematic diagram of a semiconductor device according to an embodiment of the present disclosure.

FIG. 3 is a schematic diagram of a semiconductor device according to another embodiment of the present disclosure.

FIG. 4 is a schematic diagram of a semiconductor device according to another embodiment of the present disclosure.

FIG. 5 is a schematic diagram of a semiconductor device according to another embodiment of the present disclosure.

FIG. 6 is a schematic diagram of a semiconductor device included in an interconnection structure.

### DETAILED DESCRIPTION

The following disclosure provides many different embodiments, or examples, for implementing different features of the provided subject matter. Specific examples of devices and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure describe an embodiment of a method for forming a magnetic tunnel junction memory unit (cell) in the context of a magnetoresistive random access memory (MRAM) array. For example, magnetic tunnel junction memory cells can be formed in a multilayer interconnection structure that includes wires, contacts, and vias in interconnect layers that are used in integrated circuits to connect electronic devices. According to some embodiments, the interconnection structure may be formed in a dielectric layer deposited on a semiconductor substrate in which many electronic devices such as fin field effect transistors, metal-oxide semiconductor (MOS) capacitances, diffusion resistors etc., may be formed. These electronic devices can be used as devices of integrated circuits, according to the design of integrated circuits using multilayer interconnection structures, which can connect external power sources and electrical signals to electrodes of electronic devices and internally connect electronic devices. In some embodiments, additional electronic devices may be formed on the semiconductor substrate. Examples of electronic devices formed on the semiconductor substrate include metal-insulator-metal (MIM) capacitors, thin film resistors, metal inductors, micro-electro-mechanical system (MEMS) devices, and the like. On the substrate, conductive connectors and wires on the upper layer of the interconnection structure can also be used to establish a connection structure connected to the electrodes of the electronic devices.

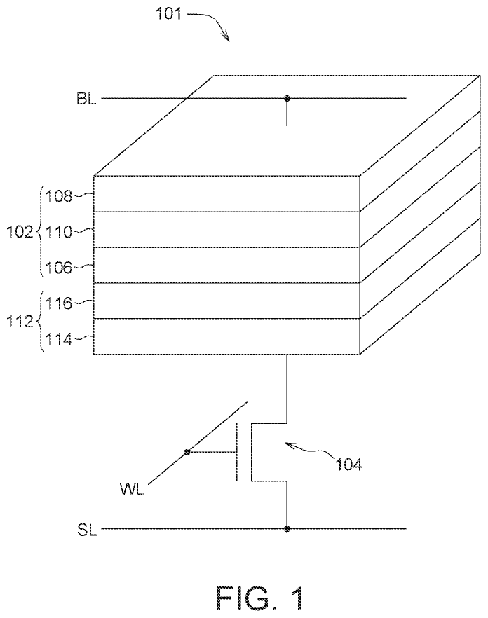

Referring to FIG. 1, a schematic diagram of a magnetic tunnel junction memory unit 101 is shown. The MTJ memory unit 101 includes a MTJ memory cell 102 and an access transistor 104. A bit line (BL) is coupled to one end of the MTJ memory cell 102, and a source line (SL) is coupled to the other end of the MTJ memory cell 102 through the access transistor 104. Therefore, when an appropriate word line (WL) voltage is applied to the gate electrode of the access transistor 104, the magnetic tunnel junction memory cell 102 may be coupled between the bit line BL and the source line SL and allows a bias voltage applying to the MTJ memory cell 102 through the bit line BL and the source line SL. Therefore, by providing proper bias conditions, the MTJ memory cell 102 can be switched between two resistance states to store data.

The magnetic tunnel junction (MTJ) includes two ferromagnetic thin films separated by a tunnel barrier layer. One of the ferromagnetic films (commonly referred to as the ferromagnetic reference layer 106) has a fixed magnetization direction, while the other ferromagnetic film (commonly referred to as the ferromagnetic free layer 108) has a variable magnetization direction. For a magnetic tunnel junction with positive tunnel magnetoresistance (TMR), if the magnetization directions of the ferromagnetic reference layer and the ferromagnetic free layer are in parallel directions, electrons will most likely tunnel through the tunnel barrier layer, making the magnetic tunnel junction in a low-resistance state. Conversely, if the magnetization orientations of the ferromagnetic reference layer and the ferromagnetic free layer are in anti-parallel orientation, electrons are less likely to tunnel through the tunnel barrier layer, making the magnetic tunneling junction in a high-resistance state.

Thus, the magnetic tunnel junction is switchable between two resistance states, a first state with a low resistance (RP: the magnetization directions of the ferromagnetic reference layer and the ferromagnetic free layer are parallel) and a second state with a high resistance (RAP: the magnetization directions of the ferromagnetic reference layer and the ferromagnetic free layer are anti-parallel). It should be noted that the magnetic tunnel junction can also have negative tunneling magnetoresistance, for example, the magnetization direction in the anti-parallel direction is low resistance, while the magnetization direction in the parallel direction is high resistance, although the following description is to describe the magnetic tunnel junctions with positive tunnel magnetoresistance (TMR). However, it should be understood that the disclosure is also applicable to magnetic tunnel junctions with negative tunneling magnetoresistance.

Due to the binary nature of the magnetic tunnel junction, the magnetic tunnel junction is used in memory cells to store digital data, wherein the low resistance state RP corresponds to the first data state (e.g., logic “0”), and the high resistance state RAP corresponds to the second data state (e.g., logic “1”). To read data from such an MTJ memory cell 101, the resistance of the MTJ (which varies between RP and RAP depending on the stored data state) can be compared to the resistance of the reference cell (e.g., designed to be a mean value between RP and RAP).

As shown in FIG. 1, the MTJ memory cell 102 includes a ferromagnetic reference layer 106, a nonmagnetic barrier layer 110 and a ferromagnetic free layer 108. The nonmagnetic barrier layer 110 separates the ferromagnetic reference layer 106 from the ferromagnetic free layer 108. Although this disclosure has been described primarily in terms of magnetic tunnel junctions, it should be understood that it is applicable to spin valve memory cell which may use a soft magnetic layer as the ferromagnetic free layer 108 and a hard magnetic layer as the ferromagnetic reference layer 106, and a nonmagnetic barrier layer 110 separating the hard and soft magnetic layers.

In some embodiments, the fixed structure 112 is a multilayer structure that includes a fixed layer 114 and a thin metal interlayer 116 above the fixed layer 114. The magnetization direction of pinned layer 114 is constrained or “pinned”. In some embodiments, the fixed layer 114 includes CoFeB, and the metal interlayer 116 includes ruthenium (Ru). The metal interlayer 116 has a predetermined thickness, which introduces a strong anti-parallel coupling between the fixed layer 114 and the ferromagnetic reference layer 106. For example, in some embodiments, the metal interlayer 116 is a transition metal, a transition metal alloy, or even an oxide to provide strong antiferromagnetic interlayer-exchange coupling (IEC). The thickness of the metal interlayer 116 is about 1.2 angstroms to about 30 angstroms. In some embodiments, the metal interlayer 116 contains ruthenium (Ru) or iridium (Ir).

In some embodiments, the nonmagnetic barrier layer 110 may include an amorphous phase barrier layer, such as aluminum oxide (AlOx) or titanium oxide (TiOx); or a crystalline phase barrier layer, such as magnesium oxide (MgO) or Magnesium aluminum spinel (MgAl₂O₄, also known as MAO). In some embodiments, the nonmagnetic barrier layer 110 is a tunnel barrier that is thin enough to allow quantum mechanical tunneling of current between the ferromagnetic free layer 108 and the ferromagnetic reference layer 106. In some other embodiments, a spin valve is used instead of the magnetic tunnel junction, and the nonmagnetic barrier layer 110 is usually a nonmagnetic metal. Examples of nonmagnetic metals include, but are not limited to, copper, gold, silver, aluminum, lead, tin, titanium, and zinc or some alloys such as brass and bronze.

The ferromagnetic free layer 108 can change its magnetization direction between two magnetization states, and the two magnetization states have different resistances corresponding to the binary data states of the memory in the memory cell 102. In some embodiments, the ferromagnetic free layer 108 may include a magnetic metal such as iron, nickel, cobalt and alloys thereof. For example, in some embodiments, the ferromagnetic free layer 108 may include cobalt, iron, and boron, such as a CoFeB ferromagnetic free layer.

For example, in a first state, the ferromagnetic free layer 108 may have a first magnetization direction, wherein the magnetization direction of the ferromagnetic free layer 108 is aligned parallel to the magnetization direction of the ferromagnetic reference layer 106, thereby providing a relatively low resistance for the MTJ memory cell 102. In a second state, the magnetization direction of the ferromagnetic free layer 108 is anti-parallel to the magnetization direction of the ferromagnetic reference layer 106, thereby providing a relatively high resistance for the MTJ memory cell 102.

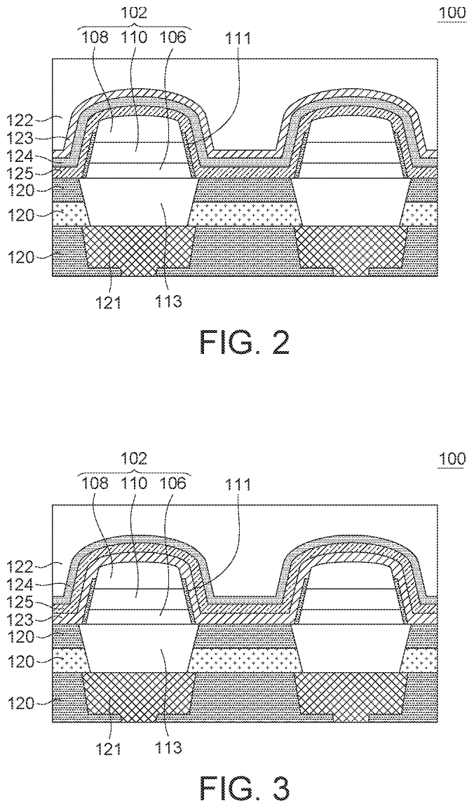

Referring to FIG. 2, a schematic diagram of a semiconductor device 100 according to an embodiment of the present disclosure is shown. The semiconductor device 100 includes a plurality of interlayer dielectric layers 120 and 122, a memory cell 102 and a first capping layer 123. The memory cell 102 is embedded in the interlayer dielectric layers 120 and 122. The first capping layer 123 covers the memory cell 102 and surrounds the sidewalls of the memory cell 102. The first capping layer 123 includes a hydrogen absorbing material, and the hydrogen absorbing material prevents hydrogen atoms from entering the memory cell 102.

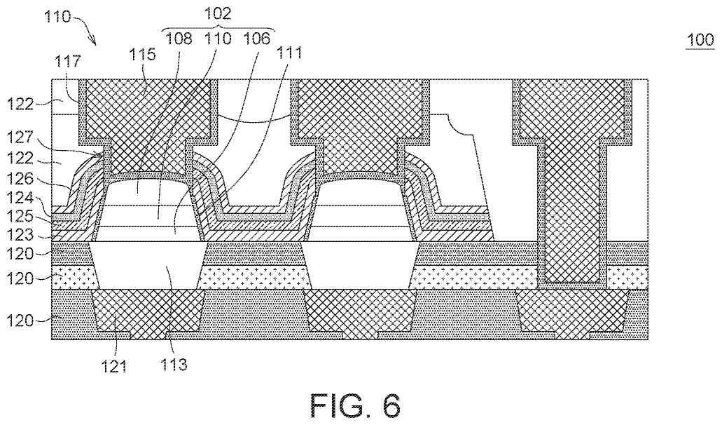

In some embodiments, the memory cell 102 as shown in FIG. 2 may be formed in the interlayer dielectric layers 120 and 122. The memory cell 102 may be electrically connected to one or more active and/or passive devices through a multilayer interconnection structure 110 (see FIG. 6) to form a functional circuit in an integrated circuit structure. The multilayer interconnection structure 110 includes a plurality of inter-metal dielectric (IMD) layers. The multilayer interconnection structure 110 further includes one or more horizontal interconnectors, such as metal lines, and/or one or more vertical interconnectors, such as metal vias (e.g., bottom electrode vias 113) and contacts 115 and 121. Metal lines have the longest dimension extending laterally, while metal vias have the longest dimension extending vertically, so that the metal vias conduct current vertically and are used to electrically connect two metal lines located on vertically adjacent levels, while metal line conduct current laterally and is used to distribute electrical signals and power within a level.

The interlayer dielectric layers 120 and 122 can be made of, for example, a low dielectric material (low k) (such as undoped silicate glass), or an oxide (such as silicon dioxide) or a very low k dielectric layer composition. The interlayer dielectric layers 120 and 122 have, for example, a k value of about 4.0 or even 2.0. In some embodiments, the interlayer dielectric layers 120 and 122 can be made of, for example, phosphosilicate glass (PSG), borophosphosilicate glass (BPSG), fluorosilicate glass (FSG), SiOxCy, spin-on-glass, spin-on-polymer, silicon oxide, silicon oxynitride, combinations thereof, or the like, formed by any suitable method, such as spin-on coating, chemical vapor deposition (CVD), plasma-enhanced CVD (PECVD), or the like. Metal lines and metal vias may include conductive materials such as copper, aluminum, tungsten, combinations thereof, or the like. In some embodiments, the metal lines and metal vias may further include one or more barrier/adhesion layers 117 to protect the individual ILD layers 120 and 122 from metal diffusion (e.g., copper diffusion). The one or more barrier/adhesion layers 117 may comprise titanium, titanium nitride, tantalum, tantalum nitride, or the like, and may be formed using PVD, CVD, ALD, or the like.

In addition, the dielectric protection layer 125 may be made of a dielectric material having a very low dielectric constant (low k), such as SiC or SiN. The dielectric protection layer 125 extends in the interlayer dielectric layers 120 and 122 and covers the top surface and the sidewalls of the memory cell 102. The dielectric protection layer 125 can be used as an etch stop layer or other purposes during the manufacturing process.

In some embodiments, the memory cell 102 is disposed between the bottom dielectric layer 120 and the top dielectric layer 122, and the bottom contact 121 and the bottom electrode via (BEVA) 113 extend through the bottom dielectric layer 120 to electrically connected to the memory cell 102. The bottom contact 121 and the bottom electrode via 113 may be made of metal, such as copper or tungsten. In some embodiments, the top dielectric layer 122 is disposed over the bottom dielectric layer 120. The memory cell 102 is embedded in the top dielectric layer 122 and is electrically connected to the BEVA 113. In the depicted embodiment, the memory cell 102 is disposed on the BEVA 113, and thus formed in an “on-via” configuration. In some other embodiments, the memory cell 102 is disposed on a metal line and thus formed in an “on-metal-line” configuration. In some embodiments, the geometric shape of the memory cell 102 may be circular, oval, rectangular, square, or the like. In some embodiments, the junction size of the memory cell 102 is in the range of about 1 nm to about 1 mm.

In some embodiments, the passivation layer 124 extends in the interlayer dielectric layer 120 and 122 and covers the top surface of the memory cell 102 and the top surface of the dielectric protection layer 125. In some embodiments, the passivation layer 124 can extend along the sidewalls of the memory cell 102 and the sidewalls of the dielectric protection layer 125. In addition, the passivation layer 124 and the dielectric protection layer 125 can further extend along the surface of the bottom dielectric layer 120.

As shown in FIG. 2, in some embodiments, the first capping layer 123 covers the top surface of the memory cell 102, the top surface of the dielectric protection layer 125 and the top surface of the passivation layer 124. In some embodiments, the first capping layer 123 may extend along the sidewalls of the memory cell 102, the sidewalls of the dielectric protection layer 125 and the sidewalls of the passivation layer 124. In addition, the first capping layer 123, the passivation layer 124 and the dielectric protection layer 125 can further extend along the surface of the bottom dielectric layer 120. The first capping layer 123, the passivation layer 124 and the dielectric protection layer 125 cover the memory cell 102 in a conformal manner, for example.

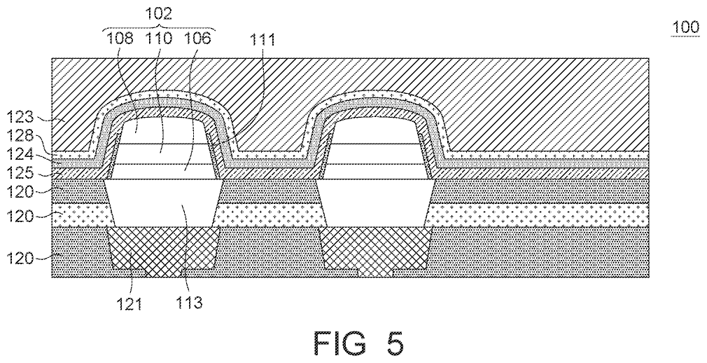

Referring to FIG. 5, in some embodiments, another dielectric layer 128 can extend along the top surface and the sidewalls of the passivation layer 124. The dielectric layer 128 may be silicon oxide or silicon oxynitride, combinations thereof, or the like. In some embodiments, the spacers 111 extend laterally along the sidewalls of the memory cell 102 in a closed path to completely enclose the memory cell 102, and the spacers 111 may be recessed into the sidewalls of the memory cell 102 (e.g., due to overetching). The spacers 111 may each be or include, for example, silicon nitride, silicon oxide, silicon oxynitride, some other suitable dielectric(s), or any combination thereof.

On the other hand, referring to FIG. 6, in some embodiments, an opening 127 can be formed on the top of the passivation layer 124, the dielectric protection layer 125 and the first capping layer 123 and/or the second capping layer 126, and the opening 127 exposes the memory cell 102 and the top contact 115 can be filled in the opening 127, so that the top contact 115 can pass through the first capping layer 123, the passivation layer 124 and the dielectric protection layer 125 and/or the second capping layer 126 to be electrically connected to the top of the memory cell 102. Therefore, the bit line BL in FIG. 1 can be electrically coupled to the top of the memory cell 102 through the top contact 115.

By using a suitable deposition technique, a top dielectric layer 122 is deposited over the memory cell 102. The top dielectric layer 122 may include a low-k dielectric material as previously discussed with respect to the IMD layer, and may have a thickness between about in the range of about 1 nm to about 1 μm. Next, the top dielectric layer 122 is removed by partially etching and depositing one or more metal materials in the opening 127 and a CMP process is performed to remove excess material outside the opening 127.

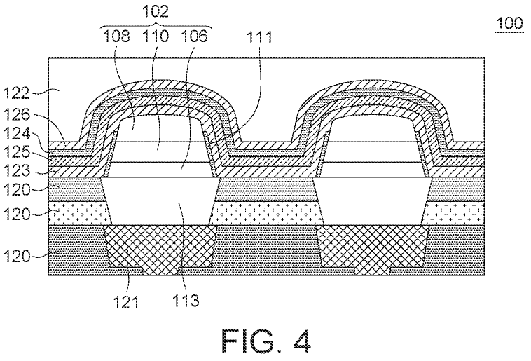

As shown in FIGS. 2 to 6, in some embodiments, the first capping layer 123, the passivation layer 124, the dielectric protection layer 125 and/or the second capping layer 126 are conformally deposited on the memory cell 102, The formation sequence is not limited, and can be selected arbitrarily to form different film layers. In some embodiments, the dielectric protection layer 125, the passivation layer 124, and the first capping layer 123 are sequentially formed on the memory cell 102 from bottom to top; or, the dielectric protection layer 125, the capping layer 123, the passivation layer 124, and the second capping layer 126 are sequentially formed on the memory cell 102; or, the first capping layer 123, the dielectric protection layer 125 and the passivation layer 124 are sequentially formed on the memory cell 102; or, the first capping layer 123, the dielectric protection layer 125, the passivation layer 124, and the second capping layer 126 are sequentially formed on the memory cell 102; or, the first capping layer 123, the dielectric protection layer 125 the second capping layer 126 and the passivation layer 124 are sequentially formed on the memory cell 102; or, only the first capping layer 123 is formed on the memory cell 102.

In some embodiments, by way of example and not limitation, the dielectric protection layer 125 and the passivation layer 124 may be silicon carbide nitride (SiCN) or aluminum nitride (AlN), which have a thickness in the range of about 150 angstroms; the dielectric protection layer 125 and the passivation layer 124 may be a silicon nitride (SiN) layer, which has a thickness in the range of about 100 angstroms to about 300 angstroms; the first capping layer 123 and the second capping layer 126 may be magnesium oxide (MgO), titanium oxide (TiO2), zirconium dioxide (ZrO₂) or aluminum oxide (Al₂O₃), which has a thickness in the range of about 10 Angstroms to about 40 Angstroms; the first capping layer 123 and the second capping layer 126 may be silicon oxide (SiO₂), which has a thickness in the range of about 100 angstroms to about 300 angstroms.

As shown in FIG. 5, in some embodiments, the first capping layer 123 may be formed on the memory cell 102 as a cell gap filling layer, for example. On the other hand, the second capping layer 126 may be formed on the memory cell 102 as a cell gap filling layer, for example. The cell gap filling layer can be silicon oxide (SiO₂) or other metal oxides that can absorb hydrogen atoms, and has a thickness in the range of about 300 angstroms to about 3000 angstroms. The cell gap filling layer may be formed by PVD, CVD, ALD, or the like.

According to some embodiments, a pre-clean process may be used to remove native copper oxide (CuO) film from the vias at the bottom of each via opening. The pre-cleaning process may include one or more sequential steps. By way of example and not limitation, the pre-clean process may include a dry etch process using a hydrogen (H₂)/ammonia (NH₃)/nitrogen trifluoride (NF₃) plasma followed by a nitrogen (N₂)/hydrogen (H₂) plasma dry etching process. During the pre-cleaning period, a direct current (DC) or radio frequency (RF) power signal may be applied to the plasma. In some embodiments, the DC power may range from about 100 Watts (W) to about 2000 Watts (W), and the RF power may range from about 50 Watts to about 500 Watts.

In order to improve the performance of transistors, current BEOL process and 3DIC packaging commonly have a hydrogen environment. However, due to the hydrogen environment, hydrogen atoms easily pass through the memory cell 102 and accumulate in the memory cell 102, affecting the barrier effect of the nonmagnetic barrier layer 110. The hydrogen atoms will lead to signification degradation of the MTJ magnetic property and the reading window and retention performance of the memory cell 102. In traditional process, there is no proper capping layer to prevent hydrogen from penetrating into the magnetic barrier layer 110, not only hindered the performance of the memory cell 102, but also limited the flexibility of the BEOL process and 3DIC package design.

In some embodiments, hydrogen is a very small atom that can become trapped in the interstices of the magnesium oxide (MgO) bulk. The MgO bonded to the metal shows a stronger hydrogen diffusivity compared to the pure Mg layer. Once the hydrogen atoms are trapped in the void, it tends to form bonds with oxygen atoms. Since the doped hydrogen atoms in the interstitial gap tend to bond with oxygen atoms, this dilutes the shared orbital features between magnesium and oxygen, leading to a symmetric distortion of the tunneling electronic state (Δ1 state), which in turn makes the tunneling magnetoresistance (TMR) of the magnetic tunnel junction reduce to a lower value. In the case of hydrogen diffused magnetic tunnel junction, the conductivity in the parallel direction is very poor, resulting in a greatly reduced tunneling magnetoresistance (TMR) value even lower than 500, i.e., 467.96%. The reason why the hydrogen atoms are trapped is that during the fabrication of any magnetic tunnel junction (MTJ), hydrogen atoms have the potential to be trapped in any interstitial gap of the tunnel barrier layer 110 due to its small size and favorable conditions.

Structurally, the magnetic tunnel junction is composed of two electrodes with a tunnel barrier therebetween, preferably an oxide material. One of the electrodes is called the free layer and the other electrode is called the fixed layer. The data is stored as the relative magnetization orientation of the two layers, with the parallel orientation as one state and the antiparallel orientation as the other. Tunneling magnetoresistance (TMR) is proportional to the difference between the respective resistances provided in transport during the parallel and anti-parallel magnetization orientations of the layers. Hydrogen is difficult to be trapped inside a pure magnesium layer at relatively low temperatures, but in most fabrication processes the temperature is much higher, under such conditions a magnesium oxide layer with a metallic interface increases hydrogen diffusion possibility into the void.

In some embodiments, the first capping layer 123 and/or the second capping layer 126 may include a hydrogen absorbing material, and the hydrogen absorbing material prevents hydrogen gas from entering the memory cell 102. The hydrogen absorbing material is, for example, magnesium oxide (MgO), titanium oxide (TiO₂), zirconium dioxide (ZrO₂), silicon dioxide (SiO₂), aluminum oxide (Al₂O₃) or other suitable metal oxides. Nanostructure also optimizes the adsorption of hydrogen. For example, carbon nanofibers, activated carbon, or nanocatalyst particles can further enhance the hydrogen absorption capacity of hydrogen absorbing materials. Hydrogen-absorbing materials are mainly metal materials composed of hydrogen-absorbing elements. The hydrogen-absorbing mechanism of hydrogen-absorbing materials is shown in the following reaction formula, M(s)+x/2 H₂(g)→MHx(s)+heat, where, M represents a solid metal alloy material. When the metal alloy is in contact with hydrogen molecules, the hydrogen molecules will first be adsorbed on the surface of the metal alloy, and the hydrogen molecules will be decomposed into hydrogen atoms by the catalyst effect of the alloy, and then the hydrogen atoms will diffuse to the internal lattice interstitial positions of the metal alloy and chemically react with the atoms of the metal alloy to form metal hydrides (MHx) and release the heat of hydrogenation at the same time. Thereby, hydrogen atoms can be trapped in the first capping layer 123 and/or the second capping layer 126 to enhance the capability of BEOL (back end of line) process and 3DIC (three-dimensional integrated circuit) package.

The present disclosure relates to a semiconductor device and a method for manufacturing the semiconductor device, wherein the first capping layer and/or the second capping layer may include a hydrogen absorbing material, and the hydrogen absorbing material prevents hydrogen gas from entering the memory cell. The hydrogen absorbing material is, for example, magnesium oxide, titanium dioxide, zirconium dioxide, silicon dioxide or other suitable metal oxides. The hydrogen will lead to significant degradation of the MTJ magnetic property and the reading window and retention performance of MRAM production due to the atomic bonds in MgO are prone to break and react with hydrogen atoms in the hydrogen environment. In the present disclosure, the capping layer may prevent hydrogen from penetrating into the memory cell, so that the hydrogen absorbing metallic/dielectric oxide in the capping layer may enhance the capability of BEOL process and 3DIC package.

According to some embodiments of the present disclosure, a semiconductor device including a plurality of interlayer dielectric layers, a memory cell, and a first capping layer is provided. The memory cell is embedded in the interlayer dielectric layers, the first capping layer covers the memory cell and surrounds the sidewalls of the memory cell, the first capping layer includes a hydrogen absorbing material, and the hydrogen absorbing material prevents hydrogen gas from entering the memory cell.

According to some embodiments of the present disclosure, a semiconductor device including a plurality of interlayer dielectric layers, a bottom electrode via, a memory cell, a first capping layer and a second capping layer is provided. The memory cell is embedded in the interlayer dielectric layers and disposed on the bottom electrode via, the first capping layer and the second capping layer cover the memory cell and surround the sidewalls of the memory cell, The first capping layer and the second capping layer respectively include a hydrogen absorbing material, and the hydrogen absorbing material prevents hydrogen gas from entering the memory cell.

According to some embodiments of the present disclosure, a method for manufacturing a semiconductor device including the following steps is provided. A plurality of interlayer dielectric layers is formed. A memory cell is formed, and the memory cell is embedded in the interlayer dielectric layers. A first capping layer is formed, the first capping layer covers the memory cell and surrounds the sidewalls of the memory cell, the first capping layer includes a hydrogen absorbing material, and the hydrogen absorbing material prevents hydrogen gas from entering the memory cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of interlayer dielectric layers;
a memory cell embedded in the interlayer dielectric layers; and
a first capping layer covers the memory cell and surrounds sidewalls of the memory cell, wherein the first capping layer comprises a hydrogen absorbing material, and the hydrogen absorbing material prevents hydrogen gas from entering the memory cell.

2. The semiconductor device according to claim 1, wherein the memory cell comprises a magnetic tunnel junction memory cell.

3. The semiconductor device according to claim 2, further comprising a multilayer interconnection structure formed in the interlayer dielectric layers, wherein the memory cell is located in the multilayer interconnection structure.

4. The semiconductor device according to claim 3, wherein the multilayer interconnection structure comprises a bottom electrode via, and the memory cell is disposed on the bottom electrode via.

5. The semiconductor device according to claim 3, wherein the multilayer interconnection structure comprises a metal contact, and the metal contact passes through the first capping layer and is electrically connected to a top of the memory cell.

6. The semiconductor device according to claim 1, further comprising a passivation layer and a dielectric protection layer, the passivation layer, the dielectric protection layer and the first capping layer extending in the interlayer dielectric layers and cover a top surface and the sidewalls of the memory cell.

7. The semiconductor device according to claim 1, wherein the hydrogen absorbing material comprises magnesium oxide (MgO), titanium oxide (TiO₂), zirconium dioxide (ZrO₂), silicon dioxide (SiO₂), or aluminum oxide (Al₂O₃).

8. The semiconductor device according to claim 1, wherein the first capping layer is formed on the memory cell as a cell gap filling layer.

9. A semiconductor device comprising:
a plurality of interlayer dielectric layers;
a bottom electrode via is disposed in the interlayer dielectric layers;
a memory cell embedded in the interlayer dielectric layers and disposed on the bottom electrode via; and
a first capping layer and a second capping layer, covering the memory cell and surrounding side walls of the memory cell, wherein the first capping layer and the second capping layer respectively comprise a hydrogen absorbing material, and the hydrogen absorbing material prevents hydrogen gas from entering the memory cell.

10. The semiconductor device according to claim 9, further comprising a passivation layer and a dielectric protection layer, wherein the passivation layer and the dielectric protection layer are located between the first capping layer and the second capping layer and extend in the interlayer dielectric layers and cover a top surface and the sidewalls of the memory cell.

11. The semiconductor device according to claim 9, further comprising a metal contact, wherein the metal contact passes through the first capping layer and the second capping layer and is electrically connected to a top of the memory cell.

12. The semiconductor device according to claim 9, wherein the hydrogen absorbing material comprises magnesium oxide (MgO), titanium oxide (TiO₂), zirconium dioxide (ZrO₂), silicon dioxide (SiO₂), or aluminum oxide (Al₂O₃).

13. The semiconductor device according to claim 9, wherein the first capping layer extends in the interlayer dielectric layers and covers a top surface and the sidewalls of the memory cell, and the second capping layer covers the first capping layer, and the second capping layer is formed on the memory cell as a cell gap filling layer.

14. A method for manufacturing a semiconductor device, comprising:
forming a plurality of interlayer dielectric layers;
forming a memory cell embedded in the interlayer dielectric layers; and
forming a first capping layer, wherein the first capping layer covers the memory cell and surrounds sidewalls of the memory cell, wherein the first capping layer comprises a hydrogen absorbing material, and the hydrogen absorbing material prevents hydrogen gas from entering the memory cell.

15. The method according to claim 14, wherein the memory cell comprises a magnetic tunnel junction memory cell.

16. The method according to claim 14, further comprising forming a bottom electrode via in the interlayer dielectric layers, wherein the memory cell is disposed on the bottom electrode via.

17. The method according to claim 14, further comprising forming a metal contact, wherein the metal contact passes through the first capping layer and is electrically connected to a top of the memory cell.

18. The method according to claim 14, further comprising forming a passivation layer and a dielectric protection layer, wherein the passivation layer, the dielectric protection layer and the first capping layer extend in the interlayer dielectric layers and cover a top surface and sidewalls of the memory cell.

19. The method according to claim 14, wherein the hydrogen absorbing material comprises magnesium oxide (MgO), titanium oxide (TiO₂), zirconium dioxide (ZrO₂), silicon dioxide (SiO₂), or aluminum oxide (Al₂O3).

20. The method according to claim 14, wherein the first capping layer is formed on the memory cell as a cell gap filling layer.
